(19) United States
(12) Patent Application Publication
(10) Pub. No.: US 2024/0206283 A1
(43) Pub. Date: Jun. 20, 2024

(54) DISPLAY DEVICE

(71) Applicant: LG Display Co., Ltd., Seoul (KR)

(72) Inventors: Eunwoo LEE, Paju-si (KR); SinWoo LEE, Paju-si (KR); MinJoo KANG, Paju-si (KR)

(73) Assignee: LG Display Co., Ltd., Seoul (KR)

(21) Appl. No.: 18/389,429

(22) Filed: Nov. 14, 2023

(30) Foreign Application Priority Data
Dec. 20, 2022 (KR) 10-2022-0179258

(51) Int. Cl. H10K 59/80

(52) U.S. Cl. CPC H10K 59/8721; H10K 59/873

(57) ABSTRACT

A display device may include, in an example, a display part for displaying an image, a metal layer disposed above the display part, and a reinforcement substrate disposed over the metal layer and made of an amorphous metal thin film. Accordingly, an existing jig can be utilized for attachment and electromagnetic waves can be effectively shielded. In another example, a display device may include a display part for displaying an image, a reinforcement substrate disposed above the display part and made of an amorphous metal thin film, and a metal layer disposed on the reinforcement substrate.

### CROSS-REFERENCE TO RELATED APPLICATIONS

This application claims the benefit of and priority to Korean Patent Application No. 10-2022-0179258 filed on Dec. 20, 2022, the entirety of which is incorporated herein by reference for all purposes.

### BACKGROUND

### 1. Technical Field

The present disclosure relates to a display device.

### 2. Discussion of the Related Art

Recently, as our society advances toward an information-oriented society, the display technologies for visually expressing an electrical information signal have rapidly evolved. Various display devices having superior performance, for example, having a slim profile, lightweight, and low power consumption, are being developed correspondingly.

Representative display devices may include a liquid crystal display device (LCD), an electro-wetting display device (EWD), and an organic light emitting display device (OLED).

Among the display devices, an electroluminescent display device including the organic light emitting display device is a self-luminous display device and can be manufactured to be lightweight and slim since it does not require a separate light source, unlike the liquid crystal display device having a separate light source. In addition, the electroluminescent display device has advantages in terms of power consumption due to a low voltage driving, and is superior in terms of color rendering, response speed, viewing angle, and contrast ratio (CR). Therefore, electroluminescent display devices are expected to be utilized in various fields of application.

The description provided in the discussion of the related art section should not be assumed to be prior art merely because it is mentioned in or associated with that section. The discussion of the related art section may include information that describes one or more aspects of the subject technology, and the description in this section does not limit the invention.

### SUMMARY

Embodiments of the present disclosure are directed to a display device that substantially obviates one or more problems due to limitations and disadvantages of the related art.

An object of the present disclosure is to provide a display device including an encapsulation unit having a novel structure.

Another object of the present disclosure is to provide a display device including an encapsulation unit having a new structure, capable of shielding electromagnetic waves and allowing for utilizing an existing magnetic jig process.

Objects of the present disclosure are not limited to the above-mentioned objects, and other objects, which are not mentioned above, can be clearly understood by those skilled in the art from the description herein.

A display device according to one or more example embodiments of the present disclosure may include a display part for displaying an image, a metal layer disposed above the display part, and a reinforcement substrate disposed over the metal layer and made of an amorphous metal thin film.

A display device according to one or more example embodiments of the present disclosure may include a display part for displaying an image, a reinforcement substrate disposed above the display part and made of an amorphous metal thin film, and a metal layer disposed on the reinforcement substrate.

One or more further example embodiments are provided in this disclosure, including the drawings.

According to one or more example embodiments of the present disclosure, by configuring an encapsulation unit with a laminated structure of a non-magnetic soft metal thin film having low rigidity and an amorphous metal thin film having high rigidity and high permeability, an existing jig can be utilized for attachment and electromagnetic waves can be effectively shielded.

The effects according one or more example embodiments of the present disclosure are not limited to those described herein, and other additional effects may be realized and attained by the descriptions provided in the present disclosure. Further, other devices, methods, features and advantages will be, or will become, apparent to one with skill in the art upon examination of the drawings and detailed description herein. It is intended that all such devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a plan view schematically illustrating a display device according to an example embodiment of the present disclosure.

FIG. 2 is an example of a cross-sectional view taken along line I-I′ of FIG. 1.

FIG. 3 is a cross-sectional view showing a sub-pixel of the display device according to an example embodiment of the present disclosure.

FIG. 4 is a table showing an example of a comparison of characteristics of amorphous metal thin films.

FIG. 5 is a table showing an example of characteristics required for the amorphous metal thin film of one or more embodiments of the present disclosure.

FIG. 6 is a schematic cross-sectional view of a display device according to another example embodiment of the present disclosure.

FIG. 7 is a table showing an example of reliability evaluation of high temperature and high moisture permeation.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements, one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, where the positional relationship between two elements (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of” or the like, one or more other elements may be located between the two elements unless a more limiting term, such as “immediate(ly),” “direct(ly),” or “close(ly),” is used. For example, when an element is described as being positioned “on,” “on a top of,” “upon,” “on top of,” “over,” “under,” “above,” “below,” “beneath,” “near,” “close to,” “adjacent to,” “beside,” “next to,” or “at or on a side of” another element, this description should be construed as including a case in which the elements contact each other directly as well as a case in which one or more additional elements are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phrase “through” may be understood to be at least partially through or entirely through. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, one or more of a plurality of elements can represent (i) one element of the plurality of elements, (ii) some elements of the plurality of elements, or (iii) all elements of the plurality of elements. Further, some elements of the plurality of elements can represent (i) one element of the plurality of elements, (ii) more than one element of the plurality of elements, or (iii) all elements of the plurality of elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

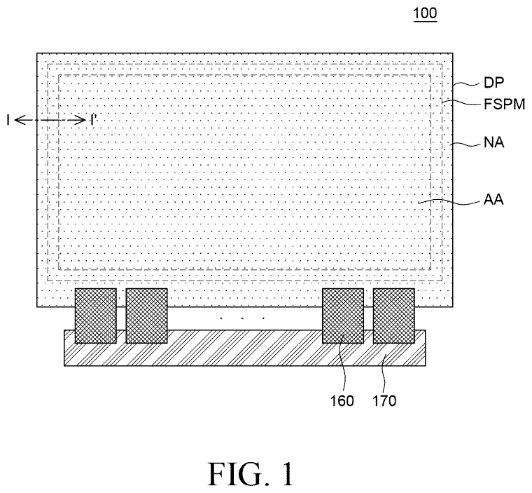

FIG. 1 is a plan view schematically illustrating a display device according to an example embodiment of the present disclosure.

Referring to FIG. 1, for example, a display device 100 according to an example embodiment of the present disclosure may include a display part DP, an encapsulation unit FSPM, flexible films 160, and a printed circuit board 170.

The display part DP may be a panel for displaying an image to a user.

Although not shown, the display part DP may include a display element for displaying an image, a driving element for driving the display element, and lines for transmitting various signals to the display element and the driving element. The display element may be defined differently depending on a type of display part DP. For example, when the display part DP is an organic light emitting display panel, the display element may be an organic light emitting element including an anode, an organic layer, and a cathode. For example, when the display part DP is a liquid crystal display panel, the display element may be a liquid crystal display element.

Hereinafter, for convenience of description and illustrative purposes, the display part DP is considered to an organic light emitting display panel, but the display part DP of the present disclosure is not limited to the organic light emitting display panel.

The display part DP may include an active area AA and a non-active area NA.

The active area AA is an area where an image is displayed on the display part DP.

A plurality of sub-pixels constituting a plurality of pixels and circuits for driving the plurality of sub-pixels may be disposed in the active area AA. The plurality of sub-pixels are minimum units constituting the active area AA, and a display element may be disposed in each of the plurality of sub-pixels, and the plurality of sub-pixels may constitute pixels. For example, an organic light emitting element including an anode, an organic layer, and a cathode may be disposed in each of the plurality of sub-pixels, but the present disclosure is not limited thereto. The circuit for driving the plurality of sub-pixels may include driving elements and lines. For example, the circuit may include thin film transistors, a storage capacitor, gate lines, a data line DL, and the like, but the present disclosure is not limited thereto.

The non-active area NA is an area in which an image is not displayed.

Although FIG. 1 illustrates that the non-active area NA surrounds the active area AA having a rectangular shape, shapes and arrangements of the active area AA and the non-active area NA are not limited to the example shown in FIG. 1.

For example, the active area AA and the non-active area NA may have shapes suitable for a design of an electronic device in which the display device 100 is mounted. For example, the active area AA may have, for example, a pentagonal shape, a hexagonal shape, a circular shape, or an elliptical shape.

In the non-active area NA, various lines and circuits for driving the organic light emitting elements of the active area AA may be disposed. For example, in the non-active area NA, driver integrated circuits (ICs) such as a gate driver IC and a data driver IC, and link lines for transmitting signals to the plurality of sub-pixels and circuits of the active area AA may be disposed, but the present disclosure is not limited thereto.

For example, the display device 100 may include various additional elements for generating various signals or driving the pixels in the active area AA. For example, additional elements for driving the pixels may include an inverter circuit, a multiplexer, an electrostatic discharge (ESD) circuit, and the like. The display device 100 may also include additional elements related to functions other than pixel driving. For example, the display device 100 may further include additional elements that provide a touch sensing function, a user authentication function (e.g., fingerprint recognition), a multi-level pressure sensing function, a tactile feedback function, and the like. The aforementioned additional elements may be positioned in the non-active area NA and/or in an external circuit connected to a connection interface.

The flexible film 160 is a film in which various parts are disposed on a flexible base film. Specifically, the flexible film 160 is a film for supplying signals to the plurality of sub-pixels and circuits of the active area AA, and may be electrically connected to the display part DP. The flexible film 160 may be disposed on one end of the display part DP and supply power voltages, data voltages, and the like to the plurality of sub-pixels and circuits of the active area AA. Thus, the number of flexible films 180 may be variously changed according to design.

The driver ICs such as a gate driver IC and a data driver IC may be disposed on the flexible film 160. The driver IC is a component that processes data for displaying an image and a driving signal for processing the data. The driver IC may be disposed using a method such as a chip on glass (COG) method, a chip on film (COF) method, or a tape carrier package (TCP) method depending on a mounting method.

The printed circuit board 170 may be disposed on or at one end of the flexible film 160 and connected to the flexible film 160. For example, the printed circuit board 170 is a component that supplies signals to the driver IC. The printed circuit board 170 may supply various signals such as driving signals and data signals to the driver IC. For example, a data driver for generating data signals may be mounted on or in the printed circuit board, and the generated data signals may be supplied to the sub-pixels and circuits of the display part DP through the flexible film 160.

Further, the encapsulation unit FSPM may be disposed on or at the display part DP.

The encapsulation unit FSPM may include a sealing member and a reinforcement substrate.

In the case of introducing an encapsulation structure which is a multilayer structure including a reinforcement substrate, rigidity and heat dissipation effects can be sufficiently secured. However, when a plastic polymer such as polyethylene terephthalate (PET) is used as the reinforcement substrate, it is difficult to respond to electromagnetic interference (EMI). In other words, an encapsulation structure which is a multilayer structure formed of a metal thin film and PET is being developed to reduce material costs and lighten its weight; however, due to its low rigidity and inability to use magnetic jigs or the like, a step difference occurs when it is bonded with an adhesive pad and thus, air bubbles are generated therein. In addition, since an upper layer thereof is formed of a non-conductive layer of PET, electromagnetic wave shielding performance may be degraded. Furthermore, the risk of damage to the display part due to low rigidity may increase.

Accordingly, in one or more embodiments of the present disclosure, by configuring the encapsulation unit FSPM with a laminated structure of a non-magnetic soft metal thin film having low rigidity and an amorphous metal thin film having high rigidity and high permeability, an existing jig can be utilized for attachment and electromagnetic waves can be effectively shielded.

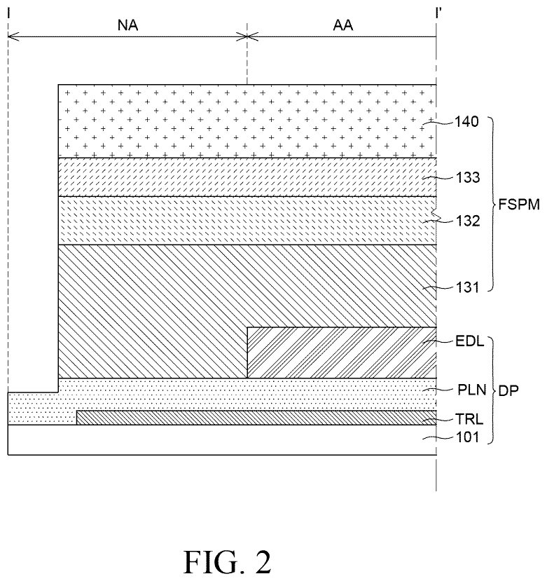

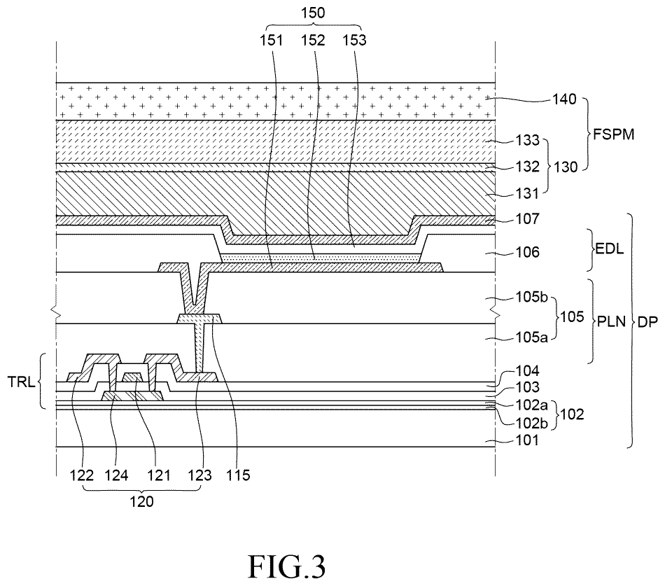

Hereinafter, the display part DP and the encapsulation unit FSPM of the present disclosure are described in more detail with reference to FIGS. 2 and 3.

FIG. 2 is an example of a cross-sectional view taken along line I-I′ of FIG. 1.

FIG. 3 is a cross-sectional view showing a sub-pixel of the display device according to an example embodiment of the present disclosure.

FIG. 2 illustrates a cross-section of one side of the display device as an example.

In FIG. 2, for convenience of description, detailed configurations of a transistor layer TRL and an emission element layer EDL are omitted.

FIG. 3 is a cross-sectional view of one sub-pixel in the display part DP according to an example embodiment of the present disclosure.

Referring to FIGS. 2 and 3, the transistor layer TRL may be disposed on the substrate 101.

For example, the substrate 101 may be a glass or plastic substrate. When the substrate 101 is a plastic substrate, a polyimide-based or polycarbonate-based material may be used to have flexibility. In particular, polyimide can be applied to a high-temperature process and is widely used as a plastic substrate because it is a material that can be coated.

A buffer layer 102 may be disposed on the substrate 101.

The buffer layer 102 is a layer for protecting various electrodes and lines from impurities such as alkali ions flowing out from the substrate 101 or lower layers thereof, and may have a multilayer structure including a first buffer layer 102a and a second buffer layer 102b. However, the present disclosure is not limited thereto. The buffer layer 102 may be formed of silicon oxide (SiOx) or silicon nitride (SiNx) or a multilayer thereof.

In addition, the buffer layer 102 may delay diffusion of moisture and oxygen penetrating into the substrate 101. The buffer layer 102 may include a multi-buffer and/or an active buffer. The active buffer protects an active layer 124 formed of a semiconductor of a driving element 120 and may perform a function of blocking various types of impurities introduced from the substrate 101. The active buffer may be formed of amorphous silicon (a-Si) or the like.

The driving element 120 may be disposed on the buffer layer 102.

For example, the driving element 120 may include the active layer 124, a gate electrode 121, a source electrode 122, and a drain electrode 123, and may be electrically connected to an organic light emitting element 150 through a connection electrode 115 to transmit a current or signal to the organic light emitting element 150.

The active layer 124 may be disposed on the buffer layer 102. In an example, the active layer 124 may be formed of polysilicon (p-Si), and in this case, a predetermined region thereof may be doped with impurities. In another example, the active layer 124 may be formed of amorphous silicon (a-Si) or may be formed of various organic semiconductor materials such as pentacene, and the like. In yet another example, the active layer 124 may be formed of an oxide semiconductor.

A gate insulating layer 103 may be disposed on the active layer 124.

The gate insulating layer 103 may be formed of an insulating inorganic material, such as silicon oxide (SiOx) or silicon nitride (SiNx), and in addition to this, it may be formed of an insulating organic material or the like.

The gate electrode 121 may be disposed on the gate insulating layer 103.

The gate electrode 121 may be formed of one or more of various conductive materials, such as nickel (Ni), chromium (Cr), magnesium (Mg), aluminum (Al), molybdenum (Mo), tungsten (W), gold (Au), or an alloy thereof.

An interlayer insulating layer 104 may be disposed on the gate electrode 121.

The interlayer insulating layer 104 may be formed of an insulating material, such as silicon oxide (SiOx) or silicon nitride (SiNx), and in addition to this, it may be formed of an insulating organic material or the like.

By selectively removing the gate insulating layer 103 and the interlayer insulating layer 104, contact holes for exposing a source region and a drain region of the active layer 124 may be formed.

The source electrode 122 and the drain electrode 123 may be disposed on the interlayer insulating layer 104.

The source electrode 122 and the drain electrode 123 may be formed of one or more of various conductive materials, such as nickel (Ni), chromium (Cr), magnesium (Mg), aluminum (Al), molybdenum (Mo), tungsten (W), gold (Au) or alloys thereof.

The source electrode 122 and the drain electrode 123 may be electrically connected to the source region and the drain region, respectively.

If necessary, an additional passivation layer formed of an inorganic insulating material may be formed to cover the source electrode 122 and the drain electrode 123.

A planarization layer PLN may be disposed on the transistor layer TRL configured as described above.

The planarization layer 105 may have a multilayer structure including at least two layers, and may include, for example, a first planarization layer 105a and a second planarization layer 105b. The first planarization layer 105a may be disposed to cover the driving element 120 while exposing portions of the source electrode 122 and the drain electrode 123 of the driving element 120.

The planarization layer 105 may extend to the non-active area NA.

The planarization layer 105 may have a thickness of about 2 μm, but is not limited thereto.

The planarization layer 105 may be an overcoat layer, but is not limited thereto.

Meanwhile, the connection electrode 115 for electrically connecting the driving element 120 and the organic light emitting element 150 may be disposed on the first planarization layer 105a. In addition, although not shown in FIG. 3, various metal layers serving as lines/electrodes such as data lines or signal lines may be disposed on the first planarization layer 105a.

In addition, the second planarization layer 105b may be disposed on the first planarization layer 105a and the connection electrode 115.

In this manner, in the display part DP according to an example embodiment of the present disclosure, the planarization layer 105 is formed of two layers due to an increase of various signal lines as the display part DP is designed to have a higher resolution. Therefore, an additional layer is provided since it is difficult to place all the lines on one layer while securing a minimum distance therebetween. Due to the addition of such an additional layer, that is, the second planarization layer 105b, a margin is created in line arrangement, and line/electrode arrangement design can be facilitated. In addition, when a dielectric material is used for the planarization layer 105 formed of multiple layers, the planarization layer 105 may also be used for forming capacitance between metal layers.

The second planarization layer 105b may be formed to expose a portion of the connection electrode 115, and the drain electrode 123 of the driving element 120 and an anode 151 of the organic light emitting element 150 may be electrically connected by the connection electrode 115.

The emission element layer EDL may be disposed on the planarization layer PLN configured as described above.

For example, the emission element layer EDL may be disposed in the active area AA and may include the organic light emitting element 150.

The organic light emitting element 150 may be configured by sequentially disposing the anode 151, a plurality of organic layers 152, and a cathode 153.

For example, the organic light emitting element 150 may include an anode 151 disposed on the planarization layer 105, an organic layer 152 disposed on the anode 151, and a cathode 153 disposed on the organic layer 152.

An electroluminescent display device may be implemented in a top emission method or bottom emission method according to an emission direction. In the case of the top emission method, a reflective layer formed of an opaque conductive material having high reflectivity, such as silver (Ag), aluminum (Al), gold (Au), molybdenum (Mo), tungsten (W), chromium (Cr), or an alloy thereof, may be added under the anode 151 such that light emitted from the organic layer 152 is reflected by the anode 151 and directed upward, that is, in a direction of the cathode 153 located thereabove. On the other hand, in the case of the bottom emission method, the anode 151 may be formed of only a transparent conductive material, such as indium tin oxide (ITO), indium zinc oxide (IZO), or indium gallium zinc oxide (IGZO). Hereinafter, for convenience of description and illustrative purposes, descriptions are provided on the assumption that the display device of the present disclosure is in the bottom emission method, unless stated otherwise; however, the present disclosure is not limited thereto.

A bank 106 may be disposed on the planarization layer 105 in an area other than an emission area.

For example, the bank 106 may have a bank hole exposing the anode 151 corresponding to the emission area. The bank 106 may be formed of an inorganic insulating material, such as silicon nitride (SiNx) or silicon oxide (SiOx) or an organic insulating material, such as BCB, acrylic resin, or imide resin.

The bank 106 may partially extend to the non-active area NA.

The bank 106 may have a thickness of about 1 μm, but is not limited thereto.

The organic layer 152 may be disposed on the anode 151 exposed by the bank 106. The organic layer 152 may include an emission layer, an electron injection layer, an electron transport layer, a hole transport layer, a hole injection layer, and the like.

The organic layer 152 may partially extend to the non-active area NA.

The cathode 153 may be disposed on the organic layer 152.

In the case of the top emission method, the cathode 153 may include a transparent conductive material. For example, the cathode 153 may be formed of indium tin oxide (ITO), indium zinc oxide (IZO), or indium gallium zinc oxide (IGZO). In the case of the bottom emission method, the cathode 153 may include any one of the group consisting of metal materials, such as gold (Au), silver (Ag), aluminum (Al), molybdenum (Mo), magnesium (Mg), palladium (Pd), and copper (Cu), or alloys thereof. Alternatively, the cathode 153 may be configured or made by stacking a layer formed of a transparent conductive material, such as indium tin oxide (ITO), indium zinc oxide (IZO), or indium gallium zinc oxide (IGZO), or a layer formed of a metal material, such as gold (Au), silver (Ag), aluminum (Al), molybdenum (Mo), magnesium (Mg), palladium (Pd), or copper (Cu), or alloys thereof, but the present disclosure is not limited thereto.

The cathode 153 may extend to the non-active area NA.

A capping layer 107 formed of a material having a high refractive index and high light absorption may be disposed on the organic light emitting element 150 to reduce diffused reflection of external light.

For example, the capping layer 107 may be an organic material layer of an organic material and may be omitted if necessary.

The capping layer 107 may extend to the non-active area NA.

The encapsulation unit FSPM may be disposed over the emission element layer EDL configured as above.

The encapsulation unit FSPM of a multilayer structure including a sealing member 130 and a reinforcement substrate 140 may be disposed over the cathode 153, but is not limited thereto.

Small-sized display panels used in mobile and portable devices have small areas, so heat is quickly dissipated from elements and there are few defects with adhesion, whereas large-sized display panels used in monitors, tablets, television receivers, and the like have large areas and thus, an encapsulation structure for optimal heat dissipation and adhesion is required.

In addition, in order to secure insufficient rigidity, the electroluminescent display device may further include a separate inner plate on an upper portion of an encapsulation substrate. In this case, it is necessary to secure a space for arranging the separate inner plate, and there are limitations in slimming and lightening of the electroluminescent display device due to the weight of the inner plate. In addition, a vertical separation space is generated by an air gap generated between the encapsulation substrate and the inner plate by the amount equal to a thickness of an adhesive tape disposed to bond the encapsulation substrate and the inner plate, thereby causing a limit to reducing heat dissipation performance.

Therefore, in one or more embodiments of the present disclosure, it is possible to apply the encapsulation unit FSPM of a multilayer structure including the sealing member 130 capable of preventing process defects and fixing the reinforcement substrate 140 having rigidity and high permeability, while removing the separate inner plate.

The sealing member 130 according to an example embodiment of the present disclosure may include a first adhesive layer 131 facing the substrate 101, a second adhesive layer 133 facing the reinforcement substrate 140, and a metal layer 132 disposed between the first adhesive layer 131 and the second adhesive layer 133.

Each of the first adhesive layer 131 and the second adhesive layer 133 may be formed of an adhesive polymer material. For example, the first adhesive layer 131 may be formed of any one of olefin-based, epoxy-based, and acrylate-based polymer materials. In addition, the second adhesive layer 133 may be formed of any one of olefin-based, epoxy-based, acrylate-based, amine-based, phenol-based, and acid anhydride-based polymer materials that do not contain a carboxyl group. In addition, for example, the second adhesive layer 133 may be formed of a polymer material that does not contain a carboxyl group for film uniformity and corrosion prevention of the metal layer 132.

To dissipate heat from the substrate 101, at least the first adhesive layer 131 among the first and second adhesive layers 131 and 133 may be formed of a mixture including particles of a metal material and an adhesive polymer material. For example, the particle of the metal material may be powder formed of nickel (Ni). The first adhesive layer 131 in direct contact with the planarization layer PLN is formed of a mixture including particles of a metal material and an adhesive polymer material, and thus may have higher thermal conductivity than that of the adhesive polymer material.

Further, the second adhesive layer 133 may be formed of a mixture including particles of a metal material and an adhesive polymer material and thus, have higher thermal conductivity than that of the adhesive polymer material.

By doing so, since a speed at which driving heat generated in the substrate 101 is dissipated through the sealing member 130 can increase, a heat dissipation effect of the substrate 101 can be improved.

To prevent moisture permeation to the emission element layer EDL, for example, the first adhesive layer 131 may be formed of a mixture that further includes an inorganic filler having moisture absorbing properties.

For example, the inorganic filler having moisture absorbing properties may be at least one of barium oxide (BaO), calcium oxide (CaO), and magnesium oxide (MgO).

Unlike the first adhesive layer 131, since the second adhesive layer 133 does not contact the emission element layer EDL, it is not required to include an inorganic filler for preventing moisture permeation. Accordingly, in one or more embodiments, the second adhesive layer 133 does not include the inorganic filler having moisture absorbing properties and may include only particles of a metal material and an adhesive polymer material. By doing so, the amount of relatively expensive inorganic filler having moisture absorbing properties, which is injected into the sealing member 130 can be reduced, and thus a cost of preparing the sealing member 130 can be reduced.

In addition, since a mixing ratio of the polymer material included in the second adhesive layer 133 may be increased, compared to that of the first adhesive layer 131, as the inorganic filler having moisture absorbing properties is not included, adhesion of the second adhesive layer 133 can be improved as compared to that of the first adhesive layer 131. Accordingly, the reinforcement substrate 140 can be more firmly fixed onto the second adhesive layer 133, and reliability of adhesion between the substrate 101 and the reinforcement substrate 140 can be further improved.

As the first adhesive layer 131 and the second adhesive layer 133 are formed in a multilayer structure, a warpage phenomenon in which the display panel is bent can be reduced, and thus reliability can also be improved.

A thickness of each of the first and second adhesive layers 131 and 133 may be limited to a critical thickness or less at which process defects are prevented. In addition, a sum of the thicknesses of the first and second adhesive layers 131 and 133 may be limited to a critical thickness or more at which reliability of fixing the reinforcement substrate 140 can be secured.

For example, the first adhesive layer 131 may have a thickness ranging from about 10 μm to 100 μm. In addition, the second adhesive layer 133 may have a thickness of about 5 μm to 30 μm.

The metal layer 132 may be formed of a thin metal material.

The metal layer 132 may be formed of a non-magnetic soft metal thin film having low rigidity of about 100 to 350 megapascal (Mpa). For example, the metal layer 132 may be formed of an aluminum (Al) thin film. Aluminum has a high shielding power against moisture and gas, and has advantages of a light weight and low cost.

For example, each of the first and second adhesive layers 131 and 133 is configured to include a polymeric material having adhesiveness, and the metal layer 132 having a relatively hard material is disposed between the first adhesive layer 131 and the second adhesive layer 133 so that the first adhesive layer 131 and the second adhesive layer 133 are bonded to one surface and the other surface of the metal layer 132, respectively, to improve adhesion.

For example, a thickness of the metal layer 132 may be limited to a value smaller than the thickness of the first adhesive layer 131 in order to minimize an increase in thickness of the sealing member 130 due to the metal layer 132. For example, the thickness of the metal layer 132 may be within a range greater than 10 μm and smaller than the thickness of the first adhesive layer 131.

Meanwhile, in one or more embodiments of the present disclosure, an amorphous metal thin film having high rigidity and high permeability can be applied as the reinforcement substrate 140. The amorphous metal thin film has high permeability, so an existing magnetic jig process can be utilized. In addition, the amorphous metal thin film has high absorption loss at high frequency, and thus, provides excellent electromagnetic wave shielding. Further, due to high rigidity, the amorphous metal thin film can prevent damage to the display part DP from external impacts.

For example, the reinforcement substrate 140 may be formed of an amorphous metal thin film of an iron (Fe)-based alloy.

As described above, a hybrid structure of a metal thin film and PET, which is being developed to reduce material costs and improve performance, has a disadvantage in that the existing magnetic jig process cannot be utilized because aluminum of the metal thin film is non-magnetic. Therefore, in manufacturing a jig structure using an adhesive pad, air bubbles are generated in a stepped portion after bonding due to a decrease in rigidity of the encapsulation structure. In addition, since an outermost layer of the hybrid structure of the metal thin film and PET is PET, it is necessary to improve a structure for electromagnetic wave shielding.

Accordingly, in one or more embodiments of the present disclosure, by configuring the encapsulation unit FSPM with a laminated structure of the metal layer 132 of the non-magnetic soft metal thin film having low rigidity and the reinforcement substrate 140 of the amorphous metal thin film having high rigidity and high permeability, a defect in the hybrid structure of the metal thin film and PET can be solved.

Amorphous metals have high rigidity, high permeability and electromagnetic field shielding properties. For example, the reinforcement substrate 140 may have high rigidity, very high permeability, and consequently superior electromagnetic field shielding properties, compared to the metal layer 132. However, the reinforcement substrate 140 has low conductivity and low reflection loss characteristics compared to the metal layer 132.

For example, the reinforcement substrate 140 may be formed of an amorphous metal thin film having a permeability of 100 to 200,000 (unit).

First of all, the amorphous metal can have high rigidity against external impacts because its crystal structure is remarkably reduced in response to weak bonds between crystal structures being destroyed against external impacts.

For example, an elastic limit, which is a limit on the amount of stretching (deformation), is between 0% and 1% for silica, steel, and titanium-based alloys, whereas amorphous metals or polymers may have 2% or more of the elastic limit.

In addition, amorphous metals and nanocrystal alloys derived therefrom are ductile materials having lower coercivity than crystalline alloys and have high permeability, so they can have high magnetic flux densities even in low external magnetic fields.

Coercivity refers to the ability of magnetization to remain in a magnetic material even after magnetizing a ferromagnetic material with an external magnetic field and then removing the external magnetic field.

In addition, the amorphous metal has low reflection loss (SE(R)) characteristics due to low conductivity, but may have high absorption loss (SE(A)) characteristics due to very high permeability.

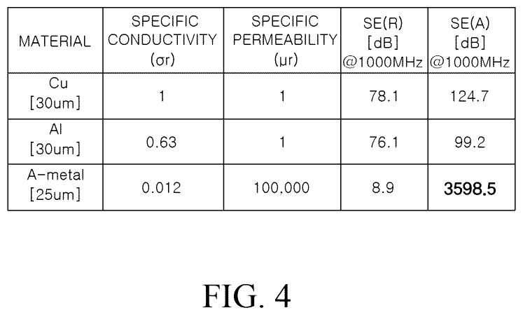

FIG. 4 is a table showing an example of a comparison of characteristics of amorphous metal thin films.

Referring to FIG. 4, in the case of copper having a thickness of 30 μm, relative conductivity and relative permeability thereof have values of 1 and 1, respectively, and a reflection loss (SE(R)) value and an absorption loss (SE(A)) value thereof may be 78.1 and 124.7, respectively.

In addition, in the case of aluminum having a thickness of 30 μm, relative conductivity and relative permeability have values of 0.63 and 1, respectively, and a reflection loss (SE(R)) value and an absorption loss (SE(A)) value thereof may be 76.1 and 99.2, respectively.

On the other hand, for example, in the case of an amorphous metal of an iron (Fe)-based alloy having a thickness of 25 μm, relative conductivity and relative permeability thereof have values of 0.012 and 100,000, respectively, and a reflection loss (SE(R)) value and an absorption loss (SE(A)) value thereof may be 8.9 and 3598.5, respectively.

As such, in the case of the amorphous metal (A-metal), it can be seen that the amorphous metal has high absorption loss (SE(A)) characteristics despite of low conductivity, due to very high magnetic permeability.

For reference, according to an electromagnetic shielding theory, a shielding effect (SE(T)) can be configured as the sum of reflection loss (SE(R)), absorption loss (SE(A)), and multiple reflection loss (SE(M)), and each shielding can be expressed by a function of a material constant of electrical conductivity and permeability of a medium and a thickness thereof.

Reflection loss (SE(R)) can be expressed by the following [Equation 1].

$$SE ( R ) = 108.1 - 10 log ( \frac{{σ}_{r}}{{μ}_{r} {f}_{MHZ}} ) \qquad [ Equation 1 ]$$

As such, it can be seen that the reflection loss (SE(R)) is independent of the thickness of the medium, increases as the conductivity of the medium increases, and decreases as the permeability of the medium and a wavelength increase. A wavelength is inversely proportional to a frequency.

The absorption loss (SE(A)) can be expressed by the following [Equation 2].

$$SE ( A ) = 131.4 {t}_{mm} \sqrt{{σ}_{r} {μ}_{r} {f}_{MHZ}} \qquad [ Equation 2 ]$$

On the other hand, it can be seen that the absorption loss (SE(A)) is determined according to the conductivity, permeability of the medium for a given thickness thereof, and a wavelength.

The multiple reflection loss (SE(M)) may be expressed by the following [Equation 3].

$$SE ( M ) = 10 log [ 1 - 2 \times {10}^{- 0.1 SE ( A )} cos ( 0.23 SE ( A ) ) + {10}^{- 0.2 SE ( A )} ] \qquad [ Equation 3 ]$$

For Equations 1 through 3, σᵣ represents relative conductivity that is based on the medium (e.g., copper in this case), and μᵣ represents relative permeability that is based on the medium (e.g., copper in this case).

Further, f_{MHZ} represents a frequency in megahertz (MHz), and tₘₘ represents a thickness of the medium (e.g., copper in this case) in millimeter (mm).

Next, a difference in electromagnetic field shielding characteristics according to metal characteristics is as follows.

Conductive magnetic metals such as common iron (Fe) are advantageous in terms of all of reflection loss (SE(R)), absorption loss (SE(A)), and multiple reflection loss (SE(M)) according to an increase in conductivity. A majority thereof corresponds to reflection loss (SE(R)).

Conductive non-magnetic metals such as copper (Cu) and aluminum (Al) are superior in reflection loss (SE(R)), but are inferior to magnetic metals in terms of absorption loss (SE(A)).

It can be seen that the amorphous metal has reduced reflection loss (SE(R)) due to low conductivity compared to crystalline metals but has excellent characteristics in terms of absorption loss (SE(A)) due to high permeability.

For example, the amorphous metal thin film of the present disclosure may include various impurities to form a stable amorphous structure with low-cost iron (Fe) as a main component and to improve physical and electromagnetic properties. For example, the amorphous metal thin film may include impurities, such as boron (B), silicon (Si), nickel (Ni), niobium (Nb), and/or copper (Cu) in iron (Fe).

For example, if an iron (Fe) content is low, it may be disadvantageous in terms of permeability and saturation magnetism, and if the iron (Fe) content is 85% or more, it is difficult to form an amorphous structure, so iron (Fe) may be included in an amount of about 65-85%.

The amorphous metal thin film according to an example embodiment of the present disclosure may include not only a complete amorphous structure but also a dispersion structure of, for example, nano-sized crystalline structures.

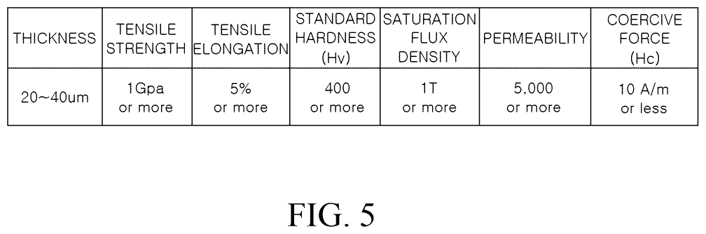

FIG. 5 is a table showing an example of characteristics required for the amorphous metal thin film of one or more embodiments of the present disclosure.

Referring to FIG. 5, properties of the amorphous metal required for the amorphous metal thin film of the present disclosure may have, for example, a thickness of 20 to 40 μm, a tensile strength of 1 gigapascal (Gpa) or more, a standard hardness (or Vickers hardness (HV)) of 400 or more, a saturation magnetic flux density of 1 tesla (T) or more, a permeability of 5,000 or more, and a coercive force (Hc) of 10 A/m or less. However, the present disclosure is not limited thereto.

An amorphous metal thin film composed of iron (Fe), silicon, and boron may have, for example, a coefficient of thermal expansion (CTE) of 4.3 ppm/° C., an elastic modulus of 120 Gpa, and a thermal conductivity of 8 W/mK at 25° C., at a thickness of 25 μm.

For example, the amorphous metal is a molten alloy without crystallinity produced by quench casting, has a random atomic structure compared to crystalline metals, and has no crystal anisotropy. In addition, the amorphous metal has soft magnetic properties, and its magnetism can be changed by heat treatment.

Meanwhile, in one or more embodiments of the present disclosure, positions of the reinforcement substrate and the metal layer may be configured interchangeably, which is described in more detail with reference to the drawings.

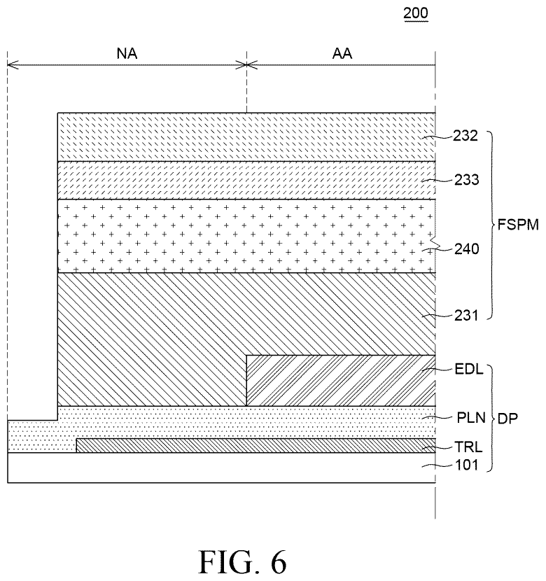

FIG. 6 is a schematic cross-sectional view of a display device according to another example embodiment of the present disclosure.

Configurations of a display device 200 according to another example embodiment of the present disclosure of FIG. 6 are substantially identical to those of the display device 100, except the encapsulation unit FSPM; thus, duplicate descriptions thereof may be omitted for brevity.

FIG. 6 illustrates a cross-section of one side of the display device 200 as an example.

In FIG. 6, for convenience of explanation, detailed configurations of the transistor layer TRL and the emission element layer EDL are omitted.

Referring to FIG. 6, the transistor layer TRL, the planarization layer PLN, and the emission element layer EDL may be disposed on the substrate 101.

The encapsulation unit FSPM of a multilayer structure may be disposed on the emission element layer EDL.

For example, a reinforcement substrate 240 may be disposed on the emission element layer EDL.

In one or more embodiments of the present disclosure, an amorphous metal thin film having high rigidity and high permeability can be applied as the reinforcement substrate 240.

For example, the reinforcement substrate 240 may be formed of an amorphous metal thin film of an iron (Fe)-based alloy.

For example, the reinforcement substrate 240 may have a thickness of about 20 μm to 40 μm.

For example, the amorphous metal thin film of the present disclosure may include low-cost iron (Fe) as a main component and impurities, such as boron (B), silicon (Si), nickel (Ni), niobium (Nb), and/or copper (Cu).

For example, if an iron (Fe) content is low, it may be disadvantageous in terms of permeability and saturation magnetism, and if the iron (Fe) content is 85% or more, it is difficult to form an amorphous structure. Accordingly, 65% to 85% of the amorphous metal thin film may contain (or may be composed of) iron (Fe).

The amorphous metal thin film according to an example embodiment of the present disclosure may include not only a complete amorphous structure but also a dispersion structure of, for example, nano-sized crystalline structures.

A first adhesive layer 231 may be disposed between the emission element layer EDL and the reinforcement substrate 240.

The first adhesive layer 231 may be formed of an adhesive polymer material, for example, any one of olefin-based, epoxy-based, urethane-based, and acrylate-based polymer materials.

For example, the first adhesive layer 231 may be formed of a mixture including particles of an adhesive polymer material and a metal material.

The first adhesive layer 231 may have a thickness of about 40 μm to about 60 μm.

For example, the first adhesive layer 231 may be formed of a mixture further including an inorganic filler having moisture absorbing properties.

For example, the inorganic filler having moisture absorbing properties may be at least one of barium oxide (BaO), calcium oxide (CaO), and magnesium oxide (MgO).

A metal layer 232 may be disposed on the reinforcement substrate 240.

The metal layer 232 may be formed of a thin metal material.

The metal layer 232 may be formed of a non-magnetic soft metal thin film having low rigidity of about 100 to 350 Mpa. For example, the metal layer 232 may be formed of an aluminum (Al) thin film. For example, the metal layer 232 may be formed of an aluminum (Al) thin film having a thickness of about 30 μm to about 50 μm.

A second adhesive layer 233 may be disposed between the reinforcement substrate 240 and the metal layer 232.

The second adhesive layer 233 may be formed of an adhesive polymer material, and for example, may be formed of any one of olefin-based, epoxy-based, acrylate-based, urethane-based, amine-based, phenol-based, and acid anhydride-based polymer materials that do not contain a carboxyl group.

For example, the second adhesive layer 233 may also be formed of a mixture including particles of a metal material and an adhesive polymer material, and in this case, it may have higher thermal conductivity than the adhesive polymer material.

The second adhesive layer 233 does not include the inorganic filler having moisture absorbing properties and may include only particles of a metal material and an adhesive polymer material.

For example, the second adhesive layer 233 may have a thickness of about 5 μm to about 30 μm.

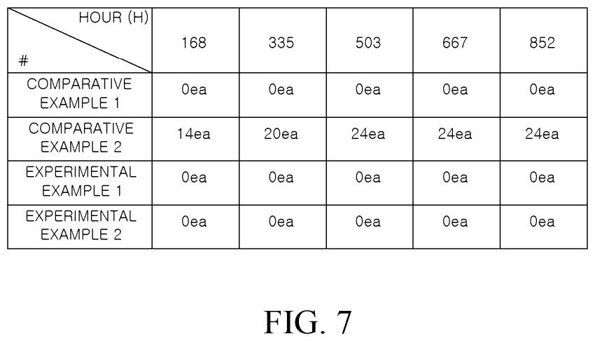

FIG. 7 is a table showing an example of reliability evaluation of high temperature and high moisture permeation.

FIG. 7 shows results of evaluating moisture permeation reliability over time under high temperature and high humidity conditions of 85° C. and 85%.

In FIG. 7, Comparative Example 1 is a case of an existing encapsulation unit provided with about 0.08 t of Inbar on an adhesive layer, and Comparative Example 2 is a case in which only a reinforcement substrate of an amorphous metal is provided on an adhesive layer.

In FIG. 7, Experimental Example 1 is a case in which the reinforcement substrate is provided on the metal layer according to an example embodiment of the present disclosure described above, and Experimental Example 2 is a case in which the metal layer is provided on the reinforcement substrate according to another example embodiment of the present disclosure described above. Here, for example, the metal layer may be formed of aluminum foil of about 40 μm, and the reinforcement substrate may be formed of an amorphous metal thin film of about 20 μm to 40 μm of iron (Fe)-based alloy.

Referring to FIG. 7, it can be seen that the case of Comparative Example 1 provided with the Inbar satisfied moisture permeation reliability, but in the case of Comparative Example 2 provided only with the reinforcement substrate of the amorphous metal, it fails to satisfy moisture permeation reliability under high temperature and high humidity conditions.

On the other hand, it can be seen that in the case of Experimental Examples 1 and 2 in which the metal layer of aluminum foil is provided on an upper portion or a lower portion of the reinforcement substrate of amorphous metal, moisture permeation reliability is satisfied. Accordingly, according to the present disclosure, the encapsulation unit can be configured with a laminated structure of a non-magnetic soft metal thin film of low rigidity and an amorphous metal thin film of high rigidity and high permeability.

In one or more aspects, a display part may refer to a display panel or a display structure. In one or more aspects, an encapsulation unit may refer to an encapsulation element, an encapsulation layer, an encapsulation structure, an encapsulation arrangement, or an encapsulation formation. A unit, a layer, an element, a structure, an arrangement and a formation may include one or more units, one or more layers, one or more elements, one or more structures, one or more arrangements, and one or more formations, respectively.

Various example embodiments and aspects of the present disclosure are described below. These are provided as examples, and do not limit the scope of the present disclosure.

According to one or more aspects of the present disclosure, a display device may include a display part for displaying an image, a metal layer disposed above the display part, and a reinforcement substrate disposed over the metal layer and made of an amorphous metal thin film.

According to one or more other aspects of the present disclosure, a display device may include a display part for displaying an image, a reinforcement substrate disposed above the display part and made of an amorphous metal thin film, and a metal layer disposed on the reinforcement substrate.

The display part may include a transistor layer, a planarization layer over the transistor layer, and an emission element layer on the planarization layer.

The metal layer may be made of a non-magnetic soft metal thin film having a rigidity of 100 to 350 Mpa.

The metal layer may be made of an aluminum (Al) thin film.

The metal layer may have a thickness of 30 μm to 50 μm.

The reinforcement substrate may be made of the amorphous metal thin film of an iron (Fe)-based alloy.

The amorphous metal thin film may include iron (Fe) and at least one impurity of boron (B), silicon (Si), nickel (Ni), niobium (Nb), and copper (Cu). 65% to 85% of the amorphous metal thin film may contain (or may be composed of) iron (Fe).

The reinforcement substrate may have a thickness of about 20 μm to about 40 μm.

The display device may further include, in an example, a first adhesive layer disposed between the display part and the metal layer, and a second adhesive layer disposed between the metal layer and the reinforcement substrate.

The display device may further include, in another example, a first adhesive layer disposed between the display part and the reinforcement substrate, and a second adhesive layer disposed between the reinforcement substrate and the metal layer.

The first adhesive layer and the second adhesive layer may be made of an adhesive polymer material.

The first adhesive layer may be made of any one of olefin-based, acrylate-based, urethane-based, and epoxy-based polymer materials.

The first adhesive layer may have a thickness of 40 μm to 60 μm.

The second adhesive layer may be formed of any one of olefin-based, epoxy-based, acrylate-based, urethane-based, amine-based, phenol-based, and acid anhydride-based polymer materials.

The second adhesive layer may be made of a mixture including particles of a metal material and the adhesive polymer material.

The second adhesive layer may have a thickness of 5 μm to 30 μm.

The reinforcement substrate may be made of an amorphous metal thin film having a tensile strength of 1 Gpa or more.

A reflection loss value of the metal layer may be greater than that of the reinforcement substrate, and an absorption loss value of the reinforcement substrate may be greater than that of the metal layer.

Although example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only and not intended to limit the technical concept or scope of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display part for displaying an image;
a metal layer disposed above the display part; and
a reinforcement substrate disposed over the metal layer and made of an amorphous metal thin film.

2. A display device, comprising:
a display part for displaying an image;
a reinforcement substrate disposed above the display part and made of an amorphous metal thin film; and
a metal layer disposed on the reinforcement substrate.

3. The display device of claim 1, wherein the display part includes:
a transistor layer;
a planarization layer over the transistor layer; and
an emission element layer on the planarization layer.

4. The display device of claim 3, wherein the metal layer is made of a non-magnetic soft metal thin film having a rigidity of 100 to 350 Mpa.

5. The display device of claim 4, wherein the metal layer is made of an aluminum (Al) thin film.

6. The display device of claim 5, wherein the metal layer has a thickness of 30 μm to 50 μm.

7. The display device of claim 3, wherein the reinforcement substrate is made of the amorphous metal thin film of an iron (Fe)-based alloy.

8. The display device of claim 3, wherein the amorphous metal thin film includes iron (Fe) and at least one impurity of boron (B), silicon (Si), nickel (Ni), niobium (Nb), and copper (Cu).

9. The display device of claim 8, wherein 65% to 85% of the amorphous metal thin film contains iron (Fe).

10. The display device of claim 7, wherein the reinforcement substrate has a thickness of about 20 μm to about 40 μm.

11. The display device of claim 1, further comprising:
a first adhesive layer disposed between the display part and the metal layer; and
a second adhesive layer disposed between the metal layer and the reinforcement substrate.

12. The display device of claim 2, further comprising:
a first adhesive layer disposed between the display part and the reinforcement substrate; and
a second adhesive layer disposed between the reinforcement substrate and the metal layer.

13. The display device of claim 11, wherein the first adhesive layer and the second adhesive layer are made of an adhesive polymer material.

14. The display device of claim 13, wherein the first adhesive layer is made of any one of olefin-based, acrylate-based, urethane-based, and epoxy-based polymer materials.

15. The display device of claim 13, wherein the first adhesive layer has a thickness of 40 μm to 60 μm.

16. The display device of claim 13, wherein the second adhesive layer is made of any one of olefin-based, epoxy-based, acrylate-based, urethane-based, amine-based, phenol-based, and acid anhydride-based polymer materials.

17. The display device of claim 16, wherein the second adhesive layer is made of a mixture including particles of a metal material and the adhesive polymer material.

18. The display device of claim 13, wherein the second adhesive layer has a thickness of 5 μm to 30 μm.

19. The display device of claim 4, wherein the reinforcement substrate is made of the amorphous metal thin film having a tensile strength of 1 Gpa or more.

20. The display device of claim 19, wherein a reflection loss value of the metal layer is greater than that of the reinforcement substrate, and an absorption loss value of the reinforcement substrate is greater than that of the metal layer.
